(19) United States
(12) Patent Application Publication
(10) Pub. No.: US 2025/0091077 A1
(43) Pub. Date: Mar. 20, 2025

(54) HOME PORT, SUBSTRATE TREATING APPARATUS, AND METHOD FOR DISCHARGING CHEMICAL SOLUTION

(71) Applicant: SAMSUNG ELECTRONICS CO, LTD., Suwon-si (KR)

(72) Inventors: Min Suk KANG, Suwon-si (KR); Young-Hoo KIM, Suwon-si (KR); Sung Hyun PARK, Suwon-si (KR); Jin Seon YOU, Suwon-si (KR); Tae-Hong KIM, Suwon-si (KR); Woo Gwan SHIM, Suwon-si (KR)

(73) Assignee: SAMSUNG ELECTRONICS CO LTD., Suwon-si (KR)

(21) Appl. No.: 18/661,139

(22) Filed: May 10, 2024

(30) Foreign Application Priority Data
Sep. 18, 2023 (KR) 10-2023-0123777

(51) Int. Cl. B05B 14/00; B05B 15/50

(52) U.S. Cl. CPC B05B 14/00; B05B 15/50

(57) ABSTRACT

A home port includes: a cylindrical body including: an open upper, a lower end, and an outlet in the lower end of the cylindrical body; a cover covering the open upper end; a pipe connected to the outlet; and a first bracket between the cover and the outlet, wherein a hole is provided in the first bracket, the first bracket has an inclined surface inclined from a first side of the first bracket to a second side of the first bracket, a vertical level of the first side of the first bracket is higher than a vertical level of the second side of the first bracket, and the hole of the first bracket is provided at the second side of the first bracket.

### CROSS-REFERENCE TO RELATED APPLICATION

This application claims priority from Korean Patent Application No. 10-2023-0123777, filed on Sep. 18, 2023, in the Korean Intellectual Property Office, the disclosure of which is incorporated by reference herein in its entirety.

### BACKGROUND

### 1. Field

The present disclosure relates to a home port where a nozzle for discharging a chemical solution to a substrate is provided, a substrate treating apparatus equipped with the home port, and a method for discharging the chemical solution.

### 2. Description of Related Art

A semiconductor device manufacturing process includes cleaning a thin film, and removing foreign substances, particles, etc. from a substrate. The cleaning is performed by placing the substrate on a spin head while a patterned surface faces upwards or downwards, supplying treating liquid to the substrate while rotating the spin head, and then drying the substrate.

A nozzle that supplies the substrate treating liquid to the substrate is mounted on a support member. The support member is configured to be movable between a waiting position and a process position by an actuator. The waiting position is a position where the nozzle waits before supplying the treating liquid to the substrate, and the process position is a position where the nozzle is positioned when treating the substrate with the treating liquid.

A chemical solution discharged from the nozzle includes a viscous treating liquid (for example, photo resist, etc.), and a fume may be left behind during discharging of this chemical solution.

Furthermore, the chemical solution is discharged from a nozzle tip disposed at an end of the nozzle, thereby causing contamination and thus clogging the nozzle tip.

### SUMMARY

One or more example embodiments provide a home port through which the chemical solution and/or the fume may be discharged without flowing backward in the home port.

Further, one or more example embodiments provide a substrate treating apparatus including a home port through which the chemical solution and/or the fume is discharged without flowing backward in the home port.

Further still, one or more example embodiments provide a method of discharging the chemical solution such that the chemical solution and/or the fume is prevented from flowing backward in a home port.

According to an aspect of an example embodiment, a home port includes: a cylindrical body including: an open upper, a lower end, and an outlet in the lower end of the cylindrical body; a cover covering the open upper end; a pipe connected to the outlet; and a first bracket between the cover and the outlet, wherein a hole is provided in the first bracket, the first bracket has an inclined surface inclined from a first side of the first bracket to a second side of the first bracket, a vertical level of the first side of the first bracket is higher than a vertical level of the second side of the first bracket, and the hole of the first bracket is provided at the second side of the first bracket.

According to an aspect of an example embodiment, a substrate treatment apparatus includes: a chamber; a chemical solution supply nozzle in the chamber, wherein the chemical solution supply nozzle includes: a supply pipe configured to supply a chemical solution to an upper surface of a substrate; and a nozzle tip configured to spray the chemical solution to the upper surface of the substrate; a home port in the chamber, wherein the home port includes an open upper end configured to receive the chemical solution discharged from the chemical solution supply nozzle; and a discharge pipe provided within the chamber and configured to discharge a residue discharged from an inner space of the home port through an outlet of the home port, wherein the home port includes a cover covering the open upper end, and a first bracket having a hole therein, a diameter of the cover is greater than a diameter of the nozzle tip, the first bracket has an inclined surface inclined from a first side of the first bracket to a second side of the first bracket, a vertical level of the first side of the first bracket is higher than a vertical level of the second side of the first bracket, and a hole is provided at the second side of the first bracket.

According to an aspect of an example embodiment, a method for discharging a chemical solution, includes: providing a home port including a cylindrical body including an open upper end, a lower end, and an outlet in the lower end; a cover covering the open upper end; a pipe connected to the outlet; and a first bracket between the cover and the outlet, wherein a hole is provided in the first bracket, the first bracket has an inclined surface inclined from a first side of the first bracket to a second side of the first bracket, a vertical level of the first side of the first bracket is higher than a vertical level of the second side of the first bracket, the hole of the first bracket is provided at the second side of the first bracket; discharging the chemical solution from a nozzle into the cylindrical body; and discharging the discharged chemical solution to the outlet.

### BRIEF DESCRIPTION OF DRAWINGS

The above and other aspects and features will be more apparent from the following description of example embodiments taken in conjunction with the attached drawings, in which:

FIG. 1 is a diagram illustrating a home port and a nozzle according to one or more example embodiments.

FIG. 2 is a diagram illustrating a home port and a nozzle according to one or more example embodiments.

FIG. 3 is a diagram illustrating a bracket as an enlarged view of an area A of FIG. 1, according to one or more example embodiments.

FIG. 4 is a perspective view of a home port and a nozzle according to one or more example embodiments.

FIG. 5 is a diagram illustrating a home port and a nozzle according to one or more example embodiments.

FIG. 6 is a diagram illustrating a home port and a nozzle according to one or more example embodiments.

FIG. 7 is a diagram illustrating a substrate treating apparatus according to one or more example embodiments.

FIG. 8 is a cross-sectional view of the home port as an enlarged view of an area C in FIG. 7, according to one or more example embodiments.

FIGS. 9, 10 and 11 are cross-sectional views of the nozzle tip as an enlarged view of an area B in FIG. 4, according to one or more example embodiments.

FIG. 12 is a diagram illustrating a substrate treating apparatus according to one or more example embodiments.

FIG. 13 is a diagram illustrating a home port and a dipping cup according to one or more example embodiments.

FIG. 14 and FIG. 15 are cross-sectional views illustrating a home port and a dipping cup according to one or more example embodiments.

FIG. 16 is a flowchart illustrating a method for discharging a chemical solution according to one or more example embodiments.

### DETAILED DESCRIPTION

For simplicity and clarity of illustration, elements in the drawings are not necessarily drawn to scale. The same reference numbers in different drawings represent the same or similar elements, and as such may perform the same or similar functionality. Further, descriptions and details of well-known steps and elements may be omitted for simplicity of the description. Furthermore, in the following detailed description of example embodiments, numerous specific details are set forth in order to provide a thorough understanding of one or more example embodiments. However, it will be apparent that example embodiments may be practiced without these specific details. In other instances, well-known methods, procedures, components, and circuits, have not been described in detail so as not to unnecessarily obscure aspects of example embodiments. Examples of various embodiments are illustrated and described further below. It will be apparent that the description herein is not intended to limit the claims to the specific example embodiments described. On the contrary, the present description is intended to cover all alternatives, modifications, and equivalents as may be included in the spirit and scope of the present disclosure as defined by the appended claims.

A shape, a size, a ratio, an angle, a number, etc., disclosed in the drawings illustrating example embodiments of are illustrative, and example embodiments are not limited thereto.

The terminology used herein is for the purpose of describing particular embodiments only and is not intended to limit the present disclosure. As used herein, the singular forms “a” and “an” are intended to include the plural forms as well, unless the context clearly indicates otherwise. The terms “comprise”, “comprising”, “include”, and “including,” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D inclusive unless otherwise specified.

According to the present description, although the terms “first”, “second”, “third”, and so on, may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, according to the present description, when a first element or layer is referred to as being present “on” or “beneath” a second element or layer, the first element may be disposed directly on or beneath the second element or may be disposed indirectly on or beneath the second element with a third element or layer being disposed between the first and second elements or layers. According to the present description of one or more example embodiments, when an element or layer is referred to as being “connected to”, or “coupled to” another element or layer, the element may be directly on, connected to, or coupled to the other element or layer, or one or more intervening elements or layers may be present. In addition, according to the present description, when an element or layer is referred to as being “between” two elements or layers, the element may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art. It will be further apparent that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, according to one or more example embodiments, two consecutive blocks may be actually executed at the same time. According to one or more example embodiments, depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of one or more example embodiments may be partially or entirely combined with each other, and may be technically associated with each other or operate with each other. One or more example embodiments may be implemented independently of each other and may be implemented together in an association relationship. Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

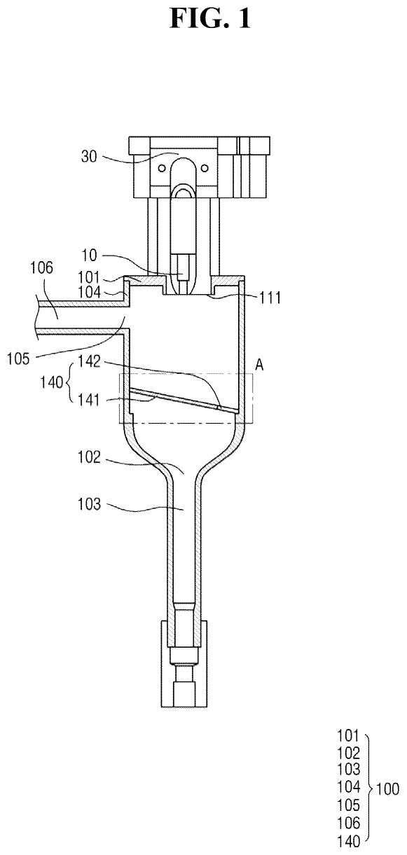

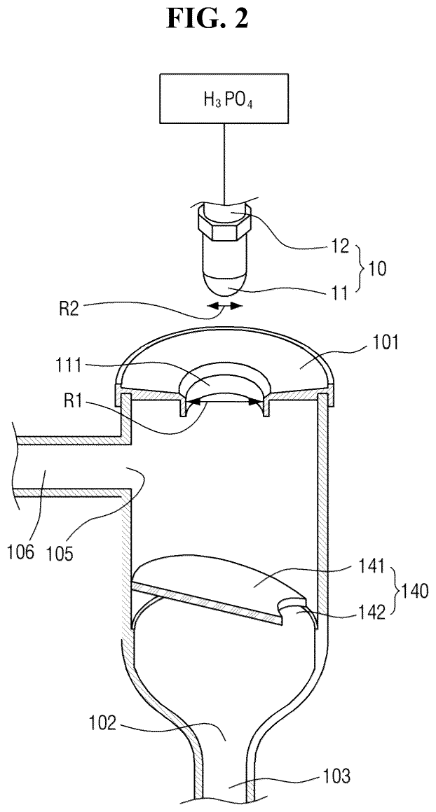

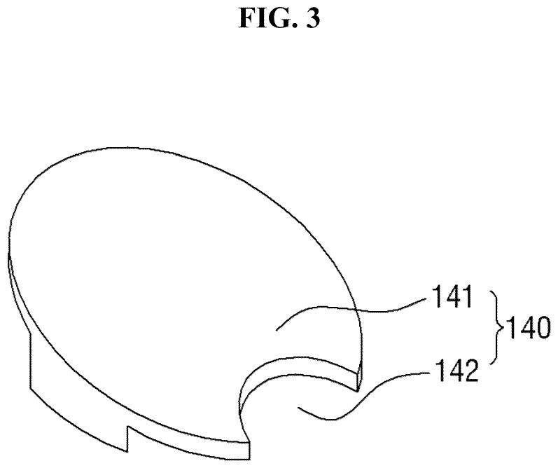

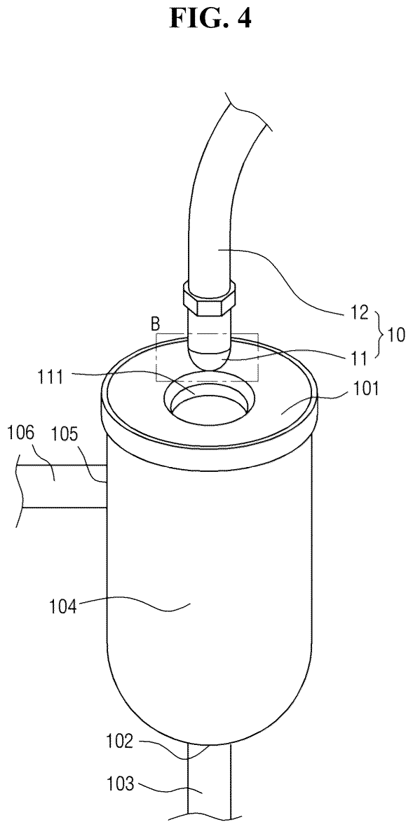

FIG. 1 is a diagram illustrating a home port and a nozzle according to one or more example embodiments. FIG. 2 is a diagram illustrating a home port and a nozzle according to one or more example embodiments. FIG. 3 is a diagram illustrating a bracket as an enlarged view of an area A of FIG. 1 according to one or more example embodiments. FIG. 4 is a perspective view of a home port and a nozzle according to one or more example embodiments.

Referring to FIGS. 1, 2, 3 and 4, a nozzle 10 may be disposed on top of a home port 100 while being mounted on a nozzle support 30. The home port 100 may include a body 104, a chemical solution outlet 102, a chemical solution pipe 103, a fume outlet 105, a fume pipe 106, a cover 101, and a bracket 140.

The nozzle 10 may be disposed on top of the home port 100 and may discharge a chemical solution. The nozzle 10 may discharge the chemical solution while being provided on top of the home port 100 and while in a state in which the nozzle is not inserted into the body 104 through an opening 111, which will be described in greater detail below. Furthermore, the nozzle 10 may discharge the chemical solution while being inserted into the body 104 through the opening 111, which will be described in greater detail below.

The body 104 may contain therein and/or discharge the chemical solution discharged from the nozzle 10. The chemical solution discharged from the nozzle 10 may include, for example, phosphoric acid (H₃PO₄) at a high temperature of over 150° C., but one or more example embodiments are not limited thereto.

The chemical solution outlet 102 may be disposed at a lower portion of the body 104. The chemical solution outlet 102 may discharge the chemical solution discharged from the nozzle 10. The chemical solution pipe 103 is connected to the chemical solution outlet 102 and may discharge the chemical solution discharged from the nozzle 10.

The fume may be produced from the chemical solution discharged from the nozzle 10. The fume outlet 105 may be disposed at a side surface of an upper portion of the body 104. The fume outlet 105 may discharge the fume produced from the chemical solution discharged from the nozzle 10. The fume pipe 106 may be connected to the fume outlet 105 and may discharge fume produced from the chemical solution discharged from the nozzle 10.

An upper surface of the body 104 may be open. The cover 101 may cover a portion of the upper surface of the body 104. The opening 111 through which the nozzle 10 may be inserted may be disposed in a center region of the upper surface of the body 104. The opening 111 may have a circular shape.

As shown according to one or more example embodiments of FIG. 2, a diameter R1 of the opening 111 may be larger than a diameter R2 of the nozzle tip 11. Because the diameter R1 of the opening 111 is larger than the diameter R2 of the nozzle tip 11, the nozzle tip 11 may be easily inserted into the body 104 through the opening 111.

The bracket 140 may be disposed inside the body 104. The bracket 140 may be disposed between the fume outlet 105 and the cover 101. The bracket 140 may include a bracket body 141 and a bracket hole 142. The bracket 140 may be connected to an inner wall of the body 104 and may be fixed thereto. The bracket 140 may have an inclined surface that extends downwardly and inclinedly from one side to the other side of the bracket 140. The bracket hole 142 may be defined at the other side of the inclined surface, wherein a vertical level of one side is higher than that of the other side thereof. The chemical solution outlet 102 and the bracket hole 142 may not overlap each other.

The fume produced from the chemical solution discharged from the nozzle 10 may contaminate the nozzle 10. To address this problem, the chemical solution may be discharged while the nozzle 10 is provided on top of the home port 100 and is not inserted into the body through the opening 111.

The chemical solution discharged from the nozzle 10 may flow through the opening 111 and may flow into the body 104. The chemical solution may be discharged to the chemical solution outlet 102 along the inclined surface of the bracket 140. Because the bracket hole 142 may not overlap the chemical solution outlet 102, the fume present in the chemical solution outlet 102 and/or a lower inner space of the body 104 may be prevented from flowing backward and/or the fume may diffuse to an upper inner space of the body 104.

An area size of the bracket hole 142 may be in a range of approximately 10% to 15% of an area size of the bracket body 141 in a plan view thereof. When the area size of the bracket hole 142 is smaller than about 10% of an area size of the bracket body 141 in the plan view thereof, the chemical solution discharged from the nozzle 10 may not be smoothly discharged to the chemical solution outlet 102. When the area size of the bracket hole 142 exceeds about 15% of the cross-sectional area of the bracket body 141 in the plan view, the fume produced from the chemical solution discharged from the nozzle 10 may not be smoothly discharged to the fume outlet 105.

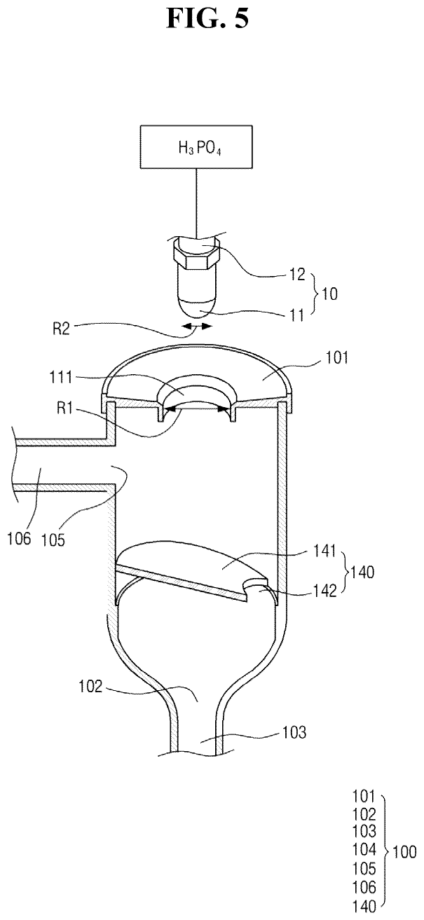

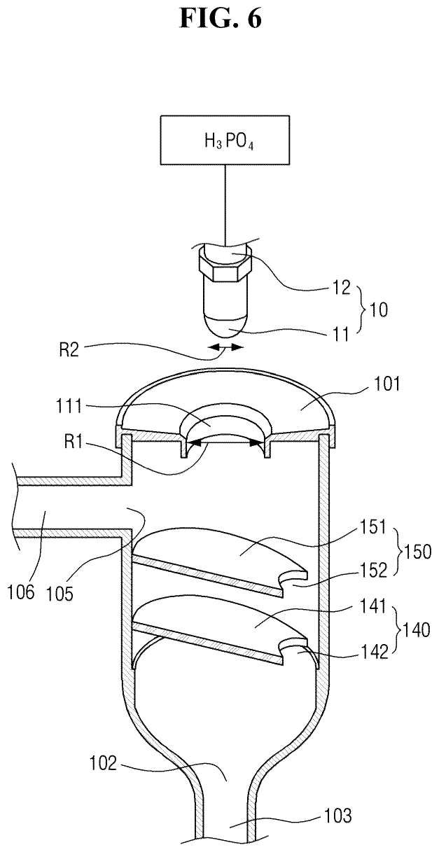

FIG. 5 is a diagram illustrating a home port and a nozzle according to one or more example embodiments. FIG. 6 is a diagram illustrating a home port and a nozzle according to one or more example embodiments.

For convenience of description, FIG. 5 and FIG. 6 are described primarily based on differences thereof from those described using FIGS. 1, 2, 3 and 4.

Referring to FIG. 5 and FIG. 6, the body 104 may further include a second bracket 150. The second bracket 150 may be disposed inside the body 104. The second bracket 150 may be disposed between the first bracket 140 and the opening 111. The second bracket 150 may include a second bracket body 151 and a second bracket hole 152. The second bracket 150 may be connected to the inner wall of the body 104 and fixed thereto. The second bracket 150 may have an inclined surface extending downwardly and inclinedly from one side to the other side thereof such that a vertical level of one side of the second bracket 150 is higher than that of the other side. The second bracket hole 152 may be defined at the other side of the inclined surface. The chemical solution outlet 102 and the second bracket hole 152 may not overlap each other.

Unlike what is shown in FIG. 5 and FIG. 6, according to one or more example embodiments the second bracket hole 152 may not overlap the first bracket hole 142. Furthermore, according to one or more example embodiments, the inclined surface of the second bracket 150 may have an inclined surface extending in a different direction from that of the first bracket 140.

The chemical solution may be discharged to the chemical solution outlet 102 along the inclined surfaces of the first bracket 140 and the second bracket 150. Because each of the first bracket hole 142 and the second bracket hole 152 may not overlap the chemical solution outlet 102, the fume present in the chemical solution outlet 102 and/or the lower inner space of the body 104 may be prevented from back-flowing and/or spreading into the upper inner space thereof.

An area size of the second bracket hole 152 may be in a range of approximately 10% to 15% of an area size of the second bracket body 151 in a plan view thereof. When the area size of the second bracket hole 152 is smaller than about 10% of the area size of the second bracket body 151 in the plan view, the chemical solution discharged from the nozzle 10 may not be smoothly discharged to the chemical solution outlet 102. When the area size of the second bracket hole 152 exceeds about 15% of the area size of the second bracket body 141 in the plan view, the fume produced from the chemical solution discharged from the nozzle 10 may not be discharged smoothly to the fume outlet 105.

It is illustrated that there are the two brackets 140 and 150 inside the home port 100. However, this is only for convenience of illustration and embodiments of the present disclosure is not limited thereto. For example, according to one or more example embodiments, there may be three or more brackets 140 and 150 inside home port 100.

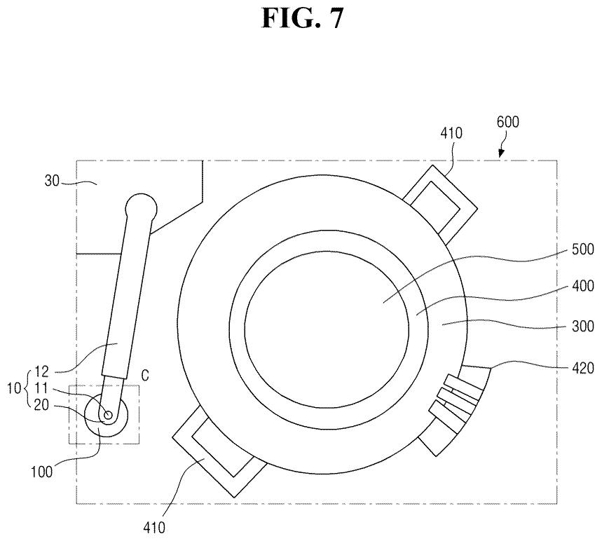

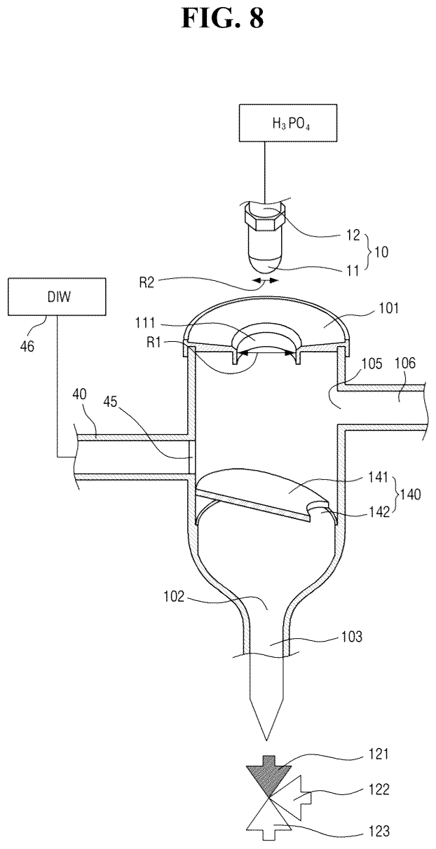

FIG. 7 is a diagram illustrating a substrate treating apparatus according to one or more example embodiments. FIG. 8 is a cross-sectional view of the home port as an enlarged view of an area C in FIG. 7.

For convenience of description, FIG. 8 is described primarily based on differences thereof from those as described according to FIGS. 1, 2, 3 and 4.

Referring to FIG. 7, the substrate treating apparatus may include a chamber 600, the nozzle support 30, the nozzle 10, the home port 100, a substrate support member 400, a substrate treating container 300, a vertically-moving unit 410, a fixed nozzle 420, and a substrate 500.

Inside the chamber 600, a substrate treating process may be performed. For example, inside the chamber 600, a substrate patterning process and a rinse process may be performed sequentially. The substrate patterning process may include a developing process, an etching process, an ashing process, or a cleaning process. The chemical solution used in the patterning process may include developer, sulfuric acid (H₂SO₄), nitric acid (HNO₃), phosphoric acid (H₃PO₄), ammonia (NH₃), hydrofluoric acid (HF), or a mixture thereof with deionized water. The chemical solution used in the patterning process may be supplied at an elevated temperature, for example, from about 100° C. to about 250° C., or from about 150° C. to about 200° C.

The nozzle support 30 may be disposed on a side surface of the substrate treating container 300. The nozzle support 30 may support the nozzle 10 so as to be positioned on top of the home port 100.

The nozzle 10 may include a nozzle tip 11, a nozzle pipe 12, and a nozzle moving unit 20. The nozzle tip 11 refers to a tip of the nozzle at an opposite side to a side thereof connected to the nozzle support 30 and may provide the chemical solution to the substrate 500 or the home port 100. The nozzle pipe 12 may provide the chemical solution to the nozzle tip 11. The nozzle moving unit 20 may freely move the nozzle in an up, down, left or right direction.

The nozzle 10 may be connected to the nozzle support 30. The nozzle 10 may be freely moved up, down, left and right by the nozzle moving unit 20 and may supply the chemical solution used in the patterning process onto the substrate 500. Before supplying the chemical solution to the substrate 500, a temperature of the chemical solution remaining in the nozzle pipe 12 and the nozzle tip 11 may become lower than a set value over time. When the temperature of the chemical solution has been lower than the set value, the temperature cannot be raised to the set value. For this reason, the chemical solution the temperature of which has been lower than the set value may be discharged and removed before supplying the chemical solution onto the substrate 500. This chemical solution discharging operation may be performed at the home port 100.

The home port 100 may be disposed on a side surface of the substrate treating container 300. The chemical solution that cannot be applied to the substrate 500 may be discharged onto the home port 100. Specifically, before supplying the chemical solution onto the substrate 500, the nozzle tip 11 may be positioned on top of the home port 100 using the nozzle moving unit 20.

The substrate treating container 300 may perform a process for treating the substrate 500. The substrate support member 400 may be disposed on the substrate treating container 300 so as to support the substrate 500 during the treating process. The vertically-moving unit 410 may change a vertical position of the substrate treating container 300 by moving the substrate support member 400 vertically.

A plurality of fixed nozzles 420 may be fixedly installed on an upper end of the substrate treating container 300 and may supply deionized water, ozone water, nitrogen (N₂), etc., to a center of the substrate 500.

Referring to FIG. 8, the chemical solution pipe 103 of the home port 100 may be connected to a dual discharge pipe 121, 122, and 123. The home port deionized water supply pipe 40 may be disposed on the side surface of the upper portion of the home port 100 so as to be in contact with the home port 100. The home port deionized water supply pipe 40 may be positioned at a lower vertical level than that of the fume outlet 105. A home port deionized water tank 46 may supply deionized water to the home port deionized water supply pipe 40.

The home port 100 may be internally contaminated by the chemical solution discharged from the nozzle 10 and the fumes produced from the chemical solution. Furthermore, after discharging the high-temperature chemical solution from the nozzle tip 11, a small portion of the chemical solution may remain on the nozzle tip 11. Therefore, in order to clean the inside of the home port 100 and the nozzle tip 11 as contaminated, the deionized water may be provided to the inside of the home port 100 via the home port deionized water supply pipe 40.

At this time, the nozzle tip 11 may move into the body 104 under an operation of the nozzle moving unit 20.

The deionized water provided into the inside of the home port 100 may be provided so as to fill the inside thereof up to a vertical level at which the nozzle tip 11 inserted into the home port 100 is entirely immersed in the deionized water such that the deionized water may clean the inside of the home port 100 and at the same time, clean the nozzle tip 11. For example, the deionized water inside the home port 100 may fill the inside thereof up to the vertical level spaced vertically upwardly by about 5 mm from a free end of the nozzle tip 11.

A deionized water flow control valve 45 may be disposed at an end of the home port deionized water supply pipe 40 in contact with the body 104. The deionized water flow control valve 45 may control whether the deionized water is supplied to the inside of the home port 100.

The dual discharge pipe 121, 122, and 123 may discharge contaminated deionized water which has been used to clean the inside of the home port 100, the chemical solution discharged from the nozzle 10, and the fume produced from the chemical solution. For example, the dual discharge pipe 121, 122, and 123 may be formed in a form of a T-shaped valve. More specifically, the second pipe 122 and the third pipe 123 may be connected to the other side of the first pipe 121 in a T shape manner.

The first pipe 121 and the second pipe 122 may be used to discharge the contaminated deionized water which has been used to clean the inside of the home port 100. The first pipe 121 and the third pipe 123 may be used to discharge the chemical solution discharged from the nozzle 10.

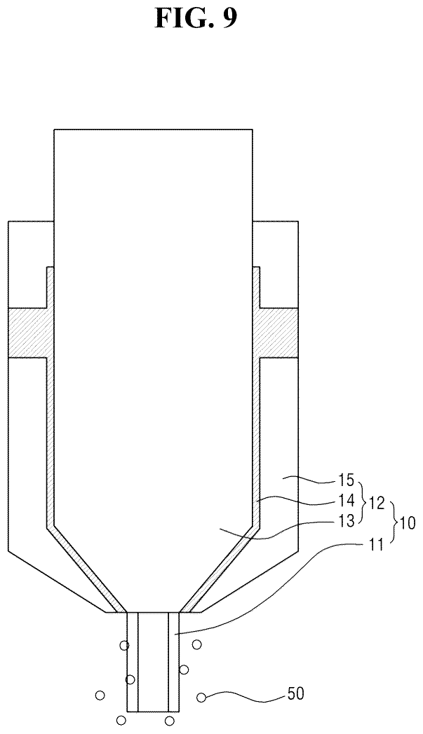

FIGS. 9, 10 and 11 are cross-sectional views of the nozzle tip as an enlarged view of an area B in FIG. 4, according to one or more example embodiments.

Referring to FIGS. 9, 10 and 11, the nozzle 10 may include the nozzle tip 11 and the nozzle pipe 12. The nozzle pipe 12 may include an in-nozzle discharge pipe 13, an in-nozzle fine supply pipe 14, and a nozzle cover 15.

The nozzle tip 11 may be connected to the nozzle pipe 12. The nozzle tip 11 may be disposed at an end of the nozzle 10. The in-nozzle discharge pipe 13 may be a pipe that discharges the high temperature chemical solution. The in-nozzle fine supply pipe 14 may be surrounded with the nozzle cover 15.

The in-nozzle fine supply pipe 14 may be disposed on a side surface of the nozzle pipe 12. The in-nozzle fine supply pipe 14 may provide the deionized water and/or nitrogen (N₂) to the nozzle tip 11.

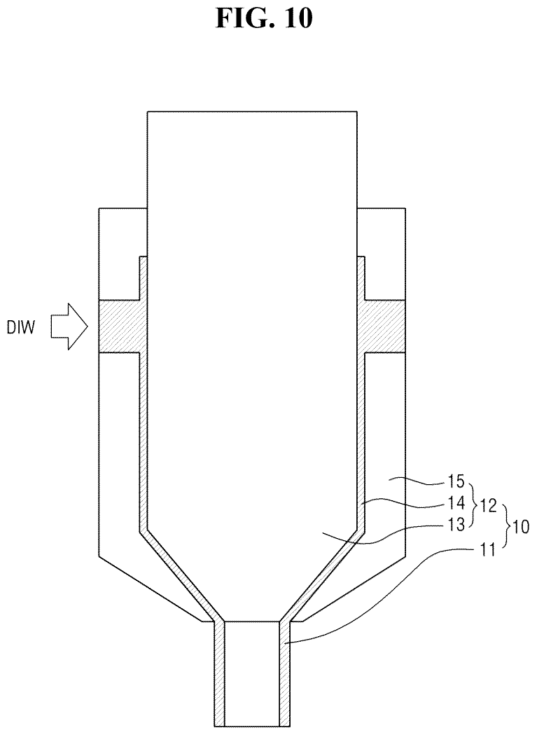

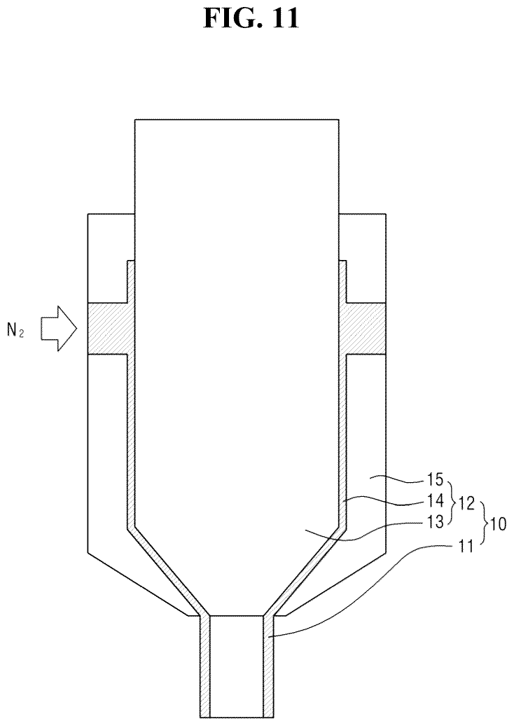

For reference, FIG. 9 is a cross-sectional view of the nozzle tip 11 showing a state in which a small portion of the chemical solution 50 remains on the nozzle tip 11 after discharging the high-temperature chemical solution therefrom, according to one or more example embodiments. FIG. 10 is a cross-sectional view of the nozzle tip 11 showing a step of providing the deionized water to the nozzle tip 11 to remove the small portion of the chemical solution 50, according to one or more example embodiments. FIG. 11 is a cross-sectional view of the nozzle tip 11 showing a step of providing the nitrogen to dry the nozzle tip 11, according to one or more example embodiments.

The in-nozzle fine supply pipe 14 may provide the deionized water to the nozzle tip 11 to remove the small portion of the chemical solution 50 remaining in the nozzle tip 11. Furthermore, the in-nozzle fine supply pipe 14 may provide the nitrogen to the nozzle tip 11 to remove the moisture resulting from the deionized water provided to the nozzle tip 11 and thus may dry the nozzle tip. Specifically, the nitrogen provided through the in-nozzle fine supply pipe 14 may be in a gaseous state.

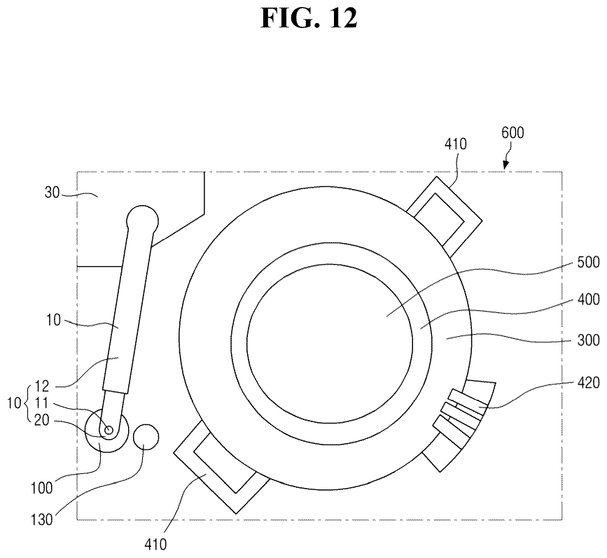

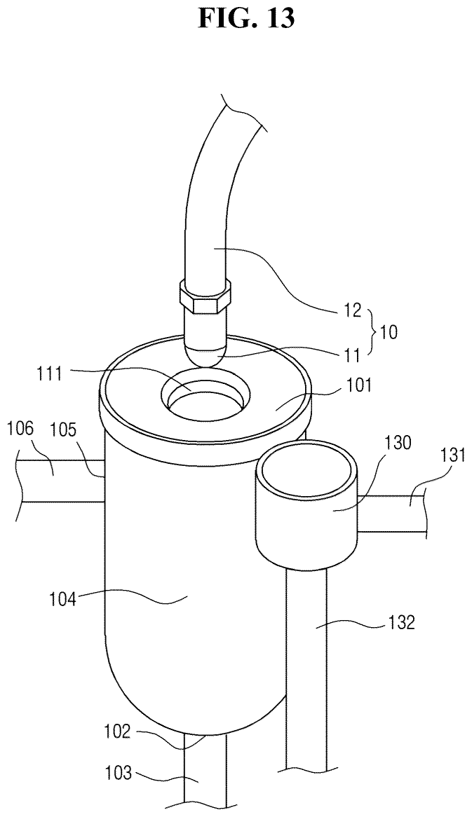

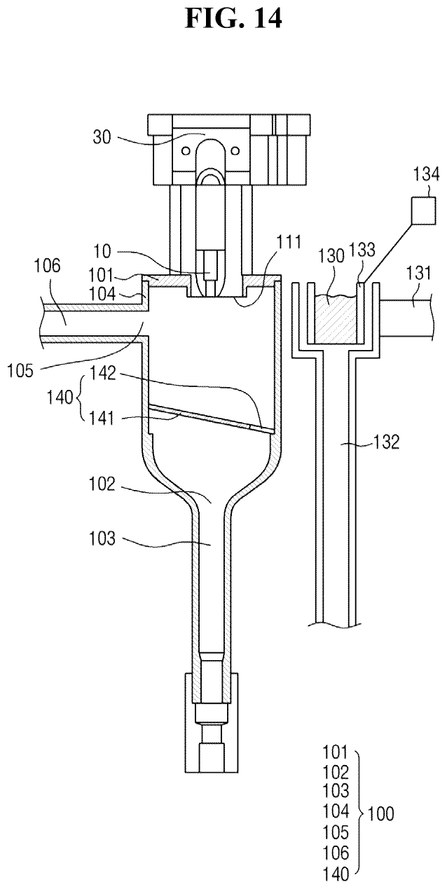

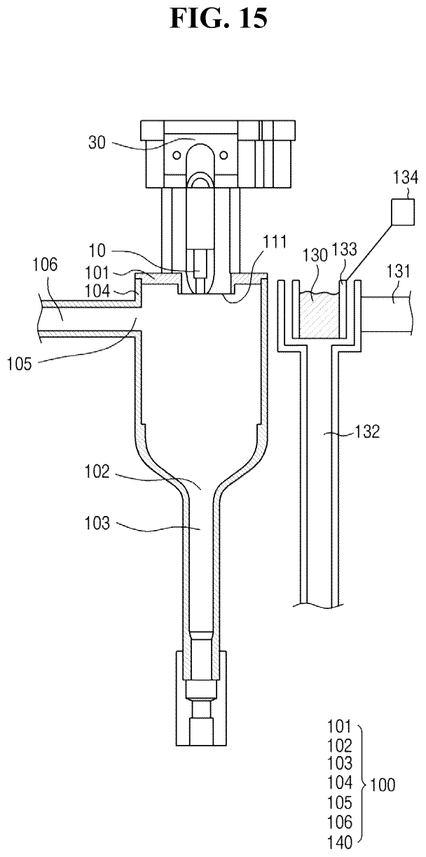

FIG. 12 is a diagram illustrating a substrate treating apparatus according to one or more example embodiments. FIG. 13 is a diagram illustrating a home port and a dipping cup according to one or more example embodiments. FIG. 14 and FIG. 15 are cross-sectional views illustrating a home port and a dipping cup according to one or more example embodiments.

For convenience of description, FIG. 12 is described primarily based on differences thereof from the description as set forth above using FIG. 7, according to one or more example embodiments. For convenience of description, FIG. 13 is described primarily based on differences thereof from the description as set forth above using FIG. 4. For convenience of description, FIG. 14 is explained primarily based on differences thereof from the description as set forth above using FIG. 1. For convenience of description, FIG. 15 is described primarily based on differences thereof from the description as set forth above using FIG. 14.

Referring to FIGS. 12, 13, and 14, the substrate treating apparatus may include the chamber 600, the nozzle support 30, the nozzle 10, the home port 100, the substrate support member 400, the substrate treating container 300, the vertically-moving unit 410, the fixed nozzle 420, the substrate 500, and a dipping cup 130.

The dipping cup 130 may be disposed on the side surface of the home port 100. The nozzle 10 may be moved on top of the dipping cup 130 under the operation of the nozzle moving unit 20.

The dipping cup 130 may be disposed on the side surface of the home port 100. The dipping cup 130 may receive cleaning liquid via a fine supply pipe 131 within the dipping cup. After cleaning has been completed, the cleaning liquid may be discharged through a cleaning liquid discharge pipe 132.

The nozzle 10 which has moved on top of the dipping cup 130 may be lowered by the nozzle moving unit 20 to bring the nozzle tip 11 into contact with the dipping cup 130. A vibrating board 133 may be disposed on the side surface of the dipping cup 130. A signal controller 134 may transmit a signal to the vibrating board 133 to generate vibration. When the vibration is applied to the dipping cup 130 from the vibrating board 133, the vibration may be transmitted to the nozzle tip 11 in contact with the dipping cup 130, such that the small portion of the chemical solution remaining on the nozzle tip 11 may be removed. For example, the vibrating board 133 may be an ultrasonic cleaner that applies ultrasonic vibration to the dipping cup 130.

After the cleaning has been completed, the cleaning liquid which has been used for cleaning may be discharged out of the dipping cup 130 through the cleaning liquid discharge pipe 132, and then the nitrogen may be provided to the nozzle tip 11 through the fine supply pipe 131 within the dipping cup. When the nitrogen has been provided to the nozzle tip 11, the nozzle tip 11 that has been cleaned with the cleaning liquid may be dried. The cleaning liquid may include, for example, deionized water.

Referring to one or more example embodiments shown in FIG. 15, the home port 100 may not include the bracket.

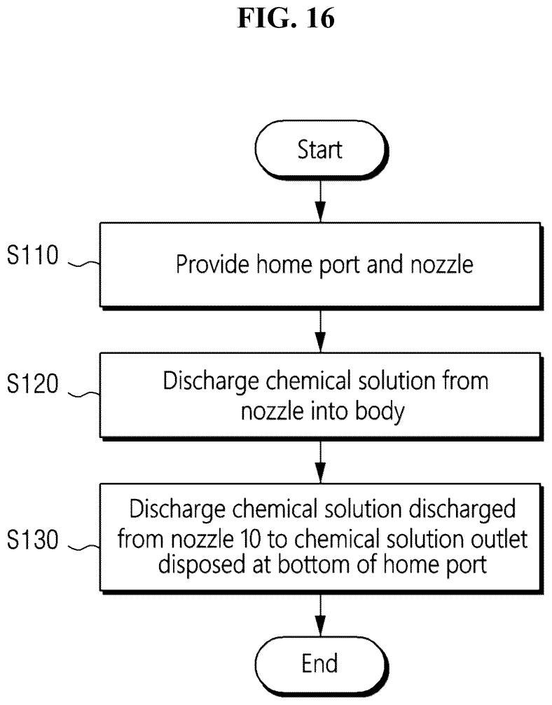

FIG. 16 is a flowchart illustrating a method for discharging a chemical solution according to one or more example embodiments. Hereinafter, for convenience of description, the method using the home port and the nozzle according to one or more example embodiments as shown in FIG. 1 will be described.

Referring to FIG. 16, the home port and the nozzle are provided in S110.

Specifically, the home port (see 100 in FIG. 1) may include the body (see 104 in FIG. 1), the outlet (see 102 in FIG. 1), the pipe (see 103 in FIG. 1), the cover (see 101 in FIG. 1), and the bracket (see 140 in FIG. 1). The nozzle (see 10 in FIG. 1) may be disposed on top of the home port 100 while being mounted on the nozzle support (see 30 in FIG. 1).

Next, the chemical solution from the nozzle 10 is discharged into the body 104 in S120.

Specifically, the chemical solution discharged from the nozzle 10 may include, for example, phosphoric acid (H₃PO₄) at a high temperature of over 150° C. Furthermore, the fume may be produced from the chemical solution discharged from the nozzle 10.

Subsequently, the chemical solution discharged from the nozzle 10 is discharged to the chemical solution outlet 102 disposed at the bottom of the home port 100 in S130.

Specifically, the chemical solution is discharged to the chemical solution outlet 102 along the inclined surface of the bracket 140. Because the bracket hole 142 and the chemical solution outlet 102 do not overlap each other, the fume present in the chemical solution outlet 102, the fume outlet 105, and/or the lower inner space of the body 104 may be prevented from flowing back and/or spreading to the upper inner space of the body 104.

Although example embodiments of the present disclosure have been described above with reference to the accompanying drawings, embodiments of the present disclosure may not be limited thereto and may be implemented in various different forms. Those of ordinary skill in the technical field to which the present disclosure belongs will be able to appreciate that the present disclosure may be implemented in other specific forms without changing the technical idea or essential features of the present disclosure. Therefore, it will be apparent that the example embodiments as described above are not restrictive but are illustrative in all respects.

While example embodiments have been particularly shown and described above, it will be apparent to those skilled in the art that many variations and modifications in form and detail may be made therein without departing from the spirit and scope of the following claims. Therefore, the disclosed example embodiments are used in a generic and descriptive sense only and not for purposes of limitation.

What is claimed is:

1. A home port comprising:
a cylindrical body comprising:
an open upper end;
a lower end; and
an outlet in the lower end of the cylindrical body;
a cover covering the open upper end;
a pipe connected to the outlet; and
a first bracket between the cover and the outlet,
wherein a hole is provided in the first bracket,
wherein the first bracket has an inclined surface inclined from a first side of the first bracket to a second side of the first bracket,
wherein a vertical level of the first side of the first bracket is higher than a vertical level of the second side of the first bracket, and
wherein the hole of the first bracket is provided at the second side of the first bracket.

2. The home port of claim 1, further comprising a second bracket between the first bracket and the outlet,
wherein a hole is provided in the second bracket.

3. The home port of claim 2, wherein the second bracket has an inclined surface inclined from a first side of the second bracket, to a second side of the second bracket,
wherein the first side of the second bracket overlaps the first side of the first bracket,
wherein the second side of the second bracket overlaps the second side of the first bracket,
wherein a vertical level of one side of the second bracket is higher than a vertical level of the second side of the second bracket, and
wherein the hole of the second bracket is provided at the second side of the second bracket.

4. The home port of claim 1, wherein the outlet does not overlap with the hole of the first bracket.

5. The home port of claim 1, wherein in a plan view of the home port, an area size of the hole of the first bracket is in a range of about 10% to 15% of an area size of the first bracket.

6. A substrate treatment apparatus comprising:
a chamber;
a chemical solution supply nozzle in the chamber, wherein the chemical solution supply nozzle comprises:
a supply pipe configured to supply a chemical solution to an upper surface of a substrate; and
a nozzle tip configured to spray the chemical solution to the upper surface of the substrate;
a home port in the chamber, wherein the home port comprises an open upper end configured to receive the chemical solution discharged from the chemical solution supply nozzle; and
a discharge pipe provided within the chamber and configured to discharge a residue discharged from an inner space of the home port through an outlet of the home port,
wherein the home port comprises:
a cover covering the open upper end; and
a first bracket having a hole therein,
wherein a diameter of the cover is greater than a diameter of the nozzle tip,
wherein the first bracket has an inclined surface inclined from a first side of the first bracket to a second side of the first bracket,
wherein a vertical level of the first side of the first bracket is higher than a vertical level of the second side of the first bracket, and
wherein a hole is provided at the second side of the first bracket.

7. The substrate treatment apparatus of claim 6, wherein the home port further comprises a second bracket between the first bracket and the outlet and having a hole therein.

8. The substrate treatment apparatus of claim 7, wherein the second bracket has an inclined surface extending at an incline from one side of the second bracket overlapping a first side of the first bracket to the second side thereof overlapping the second side of the first bracket such that a vertical level of a first side thereof is higher than a vertical level of the second side thereof, and
wherein the hole is provided at the second side of the second bracket.

9. The substrate treatment apparatus of claim 7, wherein in a plan view of the home port, an area size of the hole of the first bracket is in a range of about 10% to 15% of an area size of the first bracket, and
wherein in the plan view of the home port, an area size of the hole of the second bracket is in a range of about 10% to 15% of an area size of the second bracket.

10. The substrate treatment apparatus of claim 6, further comprising:
a deionized water supply pipe configured to provide deionized water to the home port; and
a double discharge pipe configured to discharge the chemical solution and the deionized water.

11. The substrate treatment apparatus of claim 10, wherein the double discharge pipe has a T shaped structure.

12. The substrate treatment apparatus of claim 10, wherein the deionized water inside the home port fills an inside of the home port up to a vertical level spaced vertically upwardly by about 5 mm from a free end of the nozzle tip.

13. The substrate treatment apparatus of claim 6, further comprising an in-nozzle fine supply pipe in chemical solution supply the nozzle,
wherein the in-nozzle fine supply pipe is configured to provide at least one of deionized water and nitrogen (N₂) in a gas state to the nozzle tip.

14. The substrate treatment apparatus of claim 6, further comprising:
a dipping cup on a side of the home port and configured to supply a cleaning liquid to clean the nozzle tip;
a cleaning liquid discharge pipe at a bottom of the dipping cup and configured to discharge the cleaning liquid out of the dipping cup; and
a nitrogen injector configured to spray gaseous nitrogen (N₂) to the nozzle tip.

15. The substrate treatment apparatus of claim 14, further comprising an ultrasonic cleaner configured to apply ultrasonic vibration to the dipping cup.

16. The substrate treatment apparatus of claim 14, further comprising a nozzle moving unit configured to move the nozzle tip vertically and horizontally.

17. The substrate treatment apparatus of claim 14, wherein the cleaning liquid comprises deionized water.

18. A method for discharging a chemical solution, the method comprising:
providing a home port comprising:
a cylindrical body comprising:
an open upper end;
a lower end; and
an outlet in the lower end;
a cover covering the open upper end;
a pipe connected to the outlet; and
a first bracket between the cover and the outlet,
wherein a hole is provided in the first bracket,
wherein the first bracket has an inclined surface inclined from a first side of the first bracket to a second side of the first bracket,
wherein a vertical level of the first side of the first bracket is higher than a vertical level of the second side of the first bracket,
wherein the hole of the first bracket is provided at the second side of the first bracket;
discharging the chemical solution from a nozzle into the cylindrical body; and
discharging the discharged chemical solution to the outlet.

19. The method of claim 18, wherein discharging the chemical solution from the nozzle comprises:
spraying deionized water to a nozzle tip provided at an end of the nozzle; and
spraying nitrogen to the nozzle tip.

20. The method of claim 19, wherein the spraying the nitrogen comprises spraying the nitrogen in a gas state.
